(19) United States
(12) Patent Application Publication
(10) Pub. No.: US 2007/0166917 A1
(43) Pub. Date: Jul. 19, 2007

(54) Non-volatile memory device and fabricating method therefor

(75) Inventors: Pei-Je Tzeng, Hsinchu (TW); Cha-Hsin Lin, Hsinchu (TW); Lurng-Shehng Lee, Hsinchu (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Industrial Technology Research Institute, Hsinchu (TW)

(21) Appl. No.: 11/519,655

(22) Filed: Sep. 12, 2006

(30) Foreign Application Priority Data
Dec. 30, 2005 (TW) 094147527

(51) Int. Cl. H01L 29/788; H01L 21/336

(52) U.S. Cl. 438/257; 257/315

(57) ABSTRACT

A non-volatile memory device and fabricating method therefor are provided. The non-volatile memory device includes a substrate, a first insulating layer, a conductor layer, a second insulating layer, and charge storage units. Herein, the substrate, the first insulating layer, and the conductor layer are formed, respectively. Then, the second insulating layer is disposed on the sidewalls of the first insulating layer and the conductor layer, and multiple charge storage units are formed within the second insulating film. As such, the charge storage units separated from one another effectively to improve the phenomenon of crosstalk, and provide multi-bit storage capability. Furthermore, a multi-layer charge storage structure perpendicular to and parallel to the substrate is used to enlarge the charge storage capacity.

### CROSS-REFERENCE TO RELATED APPLICATIONS

This non-provisional application claims priority under 35 U.S.C. § 119(a) on Patent Application No(s). 094147527 filed in Taiwan, R.O.C. on Dec. 30, 2005, the entire contents of which are hereby incorporated by reference.

### BACKGROUND OF THE INVENTION

1. Field of Invention

The present invention relates to a semiconductor memory device and a fabricating method therefor, and more particularly, to a non-volatile memory device and a fabricating method therefor.

2. Related Art

Generally, for non-volatile memories, there are two main ways of storing data, namely a floating gate device and a charge-trapping device. Referring to FIG. 1, it is a sectional view of a conventional non-volatile memory, which comprises a substrate 110, a tunnel dielectric layer 120, a floating gate 130, an inter-gate dielectric layer 140, a control gate 150, and a source/drain region S/D. The operating principle is illustrated as follows. Charges are injected into the floating gate 130 through the tunnel dielectric layer 120 by means of hot electron injection or Fowler-Nordheim tunneling (FN tunneling), which is the programming of data. The charges are drawn out of the floating gate 130 through the tunnel dielectric layer 120 by means of FN tunneling, which is the erasing of data. The floating gate 130 is a favorable conducting material, such that charges after being trapped are uniformly distributed on the floating gate 130 so as to make a threshold voltage shift, thereby determining whether it is memorizing or not. However, the floating gate device can only store one bit, thus raising the production cost. Furthermore, the tunnel dielectric layer 120 is prone to defects after being accessed for a period of time, so the charges in the floating gate 130 may totally disappear without being erased. In other words, when the tunnel dielectric layer 120 has defects, the data stored in the memory will be lost.

Referring to FIG. 2, it is a sectional view of another conventional non-volatile memory, which comprises a substrate 210, a charge trapping device 220, a gate 230, and a source/drain region S/D. The charge-trapping device 220 is a multi-layer structure and a charge-trapping layer 224 is provided therein. The charge-trapping layer 224 has a high deep-level trap density formed by an insulating material which is capable of easily trapping charges, such as Si₃N₄ or Al₂O₃, such that the charges can be trapped effectively and then is stored. However, the bottom layer of the charge trapping device 220 is an oxide layer 222, positive charges may be trapped therein during programming, such that a potential barrier of the oxide layer 222 is declined. Thus, the charges trapped in the charge-trapping layer 224 can easily tunnel the oxide layer 222 and be lost, thereby reducing the lifetime. Furthermore, the conventional charge-trapping layer for storing charges is a single-layer structure, so the modulation quantity of the storable charges is not high. Furthermore, the oxide layer is prone to defects after being accessed for a period of time, so the problem of current leakage still exists. Furthermore, in recent years, in order to reduce the thickness of the oxide layer for scaling down, the problem of the current leakage is increased.

Furthermore, the charges are all stored in the trap layer of continuous thin films, such as the aforementioned floating gate and the charge trapping layer, so the phenomenon of crosstalk may possibly happen due to lateral migration of the charges in the thin films, thereby causing errors in reading later.

Subsequently, nanometer dies are developed to be used as charge storage media, i.e., separated dies are formed in an insulating layer and then the charges are stored in the separated dies. Since the dies are discontinuously distributed in the insulating layer, when the tunnel dielectric layer has defects, the charges stored in the dies will not be completely lost due to the defects, such that the retention and endurance of the data storage are enhanced.

Since the charges are confined in the dies, when the device is gradually scaled down, the localized charge storage can achieve the purpose of multi-bits storages in a single device. However, the storage capacity of nanometer dies is often limited by the size thereof, and after being programmed, the voltage deviation is small, so the reading recognition cannot catch up with that of the conventional architecture, i.e., the architecture of storing charges through the trap layer of continuous thin films.

Referring to FIG. 3, it is a sectional view of a conventional non-volatile memory with nanometer dies, which comprises a substrate 310, an insulating layer 320, a gate 330, and a source/drain region S/D. The insulating layer 320 has separated dies N to store charges, as descried in U.S. Pat. No. 6,724,038. Herein, the phenomenon of crosstalk between dies is effectively reduced through the separated nanometer die regions. However, the charge storage media, i.e., nanometer dies, are adjacent to the charge injection position, so the problem of insufficient charge storage capacity of the nanometer dies still exists.

Referring to FIG. 4, it is a sectional view of another conventional non-volatile memory with nanometer dies, which comprises a substrate 410, a gate insulating layer 420, a gate 430, a dielectric layer 440, a pull-up electrode 450, and a source/drain region S/D. The gate-insulating layer 420 is a double-layer structure. The lower layer is an insulating layer 422, and the upper layer is an oxide layer 424. The oxide layer 424 has the separated dies N to store charges, as described in U.S. Pat. No. 6,872,614. Herein, the oxide layer of high dielectric material and the nanometer dies are used as storage media, but when the device is downsized, the migration of the storage charges still affects the effect of the multi-modal storage.

Therefore, the charge storage capacity of the non-volatile memory with dies still has the potential to be improved.

### SUMMARY OF THE INVENTION

In view of the aforementioned problems, the object of the present invention is to provide a non-volatile memory device and a fabricating method thereof, so as to solve the problems existing in the prior arts, such as migration and loss of storage charges, and insufficient charge capacity of nanometer dies.

Therefore, in order to achieve the aforementioned objects, the non-volatile memory device disclosed in the present invention comprises a substrate, a first insulating layer, a conductor layer, a second insulating layer, and charge storage units. Herein, the substrate, the first insulating layer, and the conductor layer are sequentially laminated. The second insulating film is disposed on the sidewalls of the first insulating layer and the conductor layer, and multiple charge storage units are formed within the second insulating layer.

Herein, the second insulating layer separates the charge storage units from one another, and thus crosstalk between the charge storage units is effectively eliminated. Furthermore, the charge storage units in the second insulating layer are arranged in a matrix of more than two dimensions. In other words, the charge storage units are arranged in at least two layers in a direction substantially perpendicular to the surface of the substrate, and arranged in at least one row in a direction substantially parallel to the surface of the substrate, so as to increase the charge storage capacity and provide multi-bit storage capability.

Furthermore, the material the first insulating layer is the same as or different from that of the second insulating layer. The dielectric constant of the first insulating layer can be greater than that of the second insulating layer, so as to increase a coupling ratio of circuit operation and further accelerate the operation speed.

The present invention further discloses a method of fabricating the non-volatile memory, which comprises providing a substrate; sequentially laminating a first insulating layer and a conductor layer on the substrate; then, forming a second insulating layer on the sidewalls of the first insulating layer and the conductor layer, wherein multiple separated charge storage units are formed in the second insulating layer.

Herein, the second insulating layer separates the charge storage units from one another, and thus crosstalk between the charge storage units is effectively eliminated. Furthermore, the charge storage units in the second insulating layer are arranged in a matrix of more than two dimensions. In other words, the charge storage units are arranged in at least two layers in the direction substantially perpendicular to the surface of the substrate, and arranged in at least one row in the direction substantially parallel to the surface of the substrate, so as to increase the charge storage quantity and provide multi-bit storage capability.

Additionally, the material of the first insulating layer is the same as or different from that of the second insulating layer. The dielectric constant of the first insulating layer can be larger than that of the second insulating layer, so as to increase a coupling ratio of circuit operation and further accelerate the operation speed.

The second insulating layer is formed through a mask process, and before or after the mask process, an annealing process is performed to nucleate the material of the charge storage units in the second insulating layer.

The features and practice of the preferred embodiments of the present invention will be illustrated below in detail with reference to the drawings.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIG. 1 is a sectional view of the conventional non-volatile memory device;

FIG. 2 is a sectional view of another conventional non-volatile memory device;

FIG. 3 is a sectional view of the conventional non-volatile memory device with nanometer dies;

FIG. 4 is a sectional view of another conventional non-volatile memory device with nanometer dies;

FIGS. 5A to 5C are flow charts of fabricating the non-volatile memory device according to one embodiment of the present invention;

FIG. 5D is a sectional view of the non-volatile memory device according to one embodiment of the present invention;

FIG. 5E is a sectional view of the non-volatile memory device according to another embodiment of the present invention;

FIG. 5F is a sectional view of the non-volatile memory device according to still another embodiment of the present invention;

FIGS. 6A to 6D are flow charts of forming a first insulating layer and a conductor according to one embodiment of the method of fabricating the non-volatile memory provided by the present invention;

FIGS. 7A to 7E are flow charts of forming a second insulating layer according to the first embodiment of the method of fabricating the non-volatile memory provided by the present invention;

FIGS. 8A to 8E are flow charts of forming a second insulating layer according to the second embodiment of the method of fabricating the non-volatile memory provided by the present invention;

FIGS. 9A to 9E are flow charts of forming a second insulating layer according to the third embodiment of the method of fabricating the non-volatile memory provided by the present invention;

FIGS. 10A to 10E are flow charts of forming a second insulating layer according to the fourth embodiment of the method of fabricating the non-volatile memory provided by the present invention; and

FIGS. 11A to 11E are flow charts of forming a second insulating layer according to the fifth embodiment of the method of fabricating the non-volatile memory provided by the present invention.

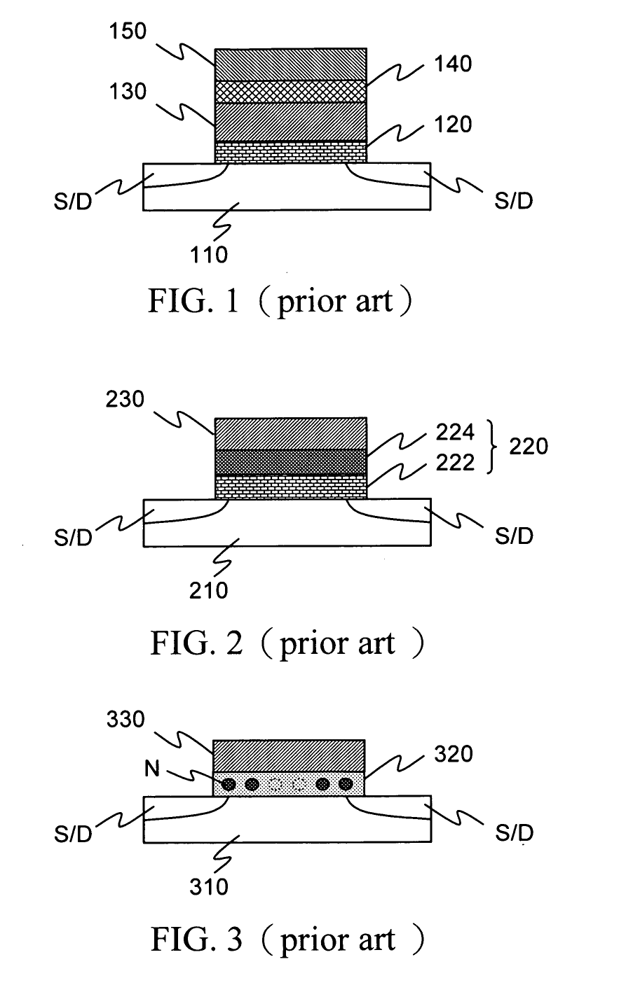

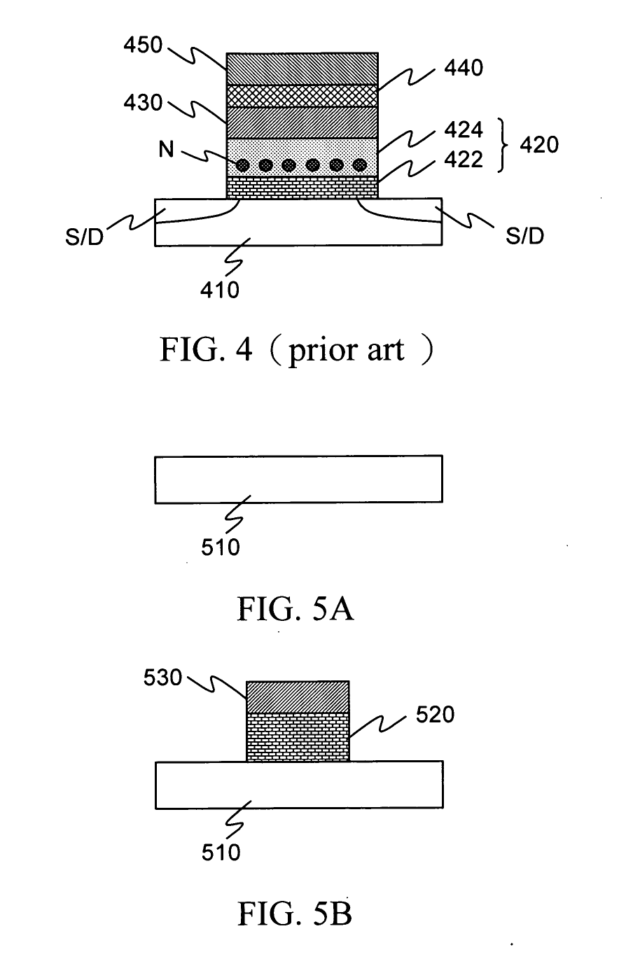

### DETAILED DESCRIPTION OF THE INVENTION

Specific embodiments will be provided to illustrate the content of the present invention in detail with reference to drawings. The symbols mentioned in the specification refer to the symbols in the figures.

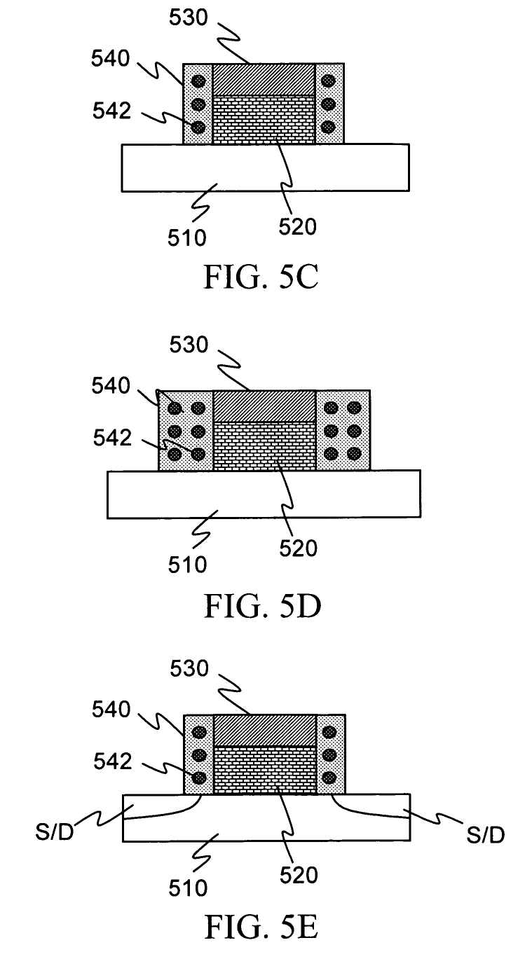

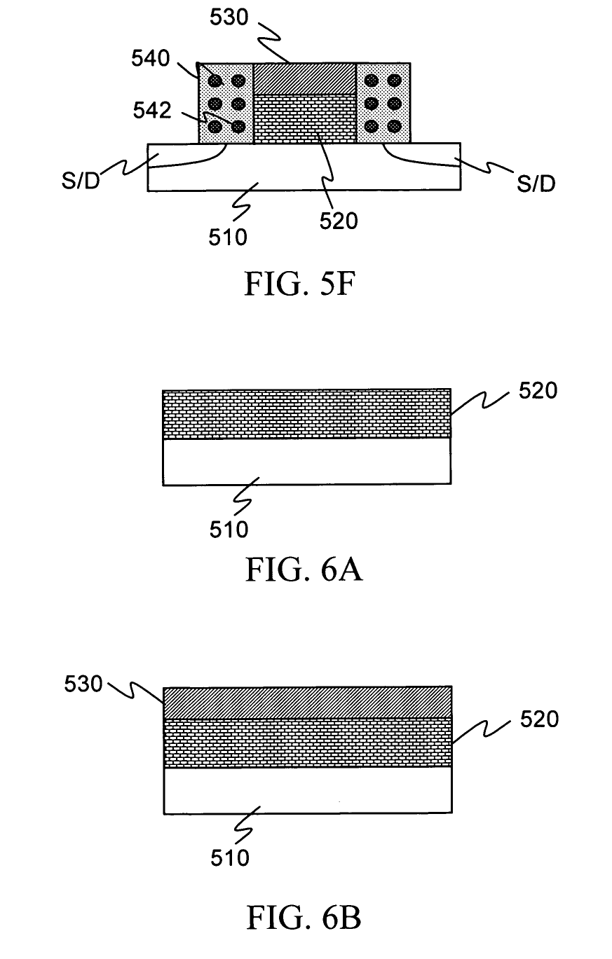

Referring to FIGS. 5A to 5C, flow charts of fabricating the non-volatile memory device according to one embodiment of the present invention are shown.

As shown in FIG. 5A, a substrate 510 such as a semiconductor substrate is firstly provided. The material of the substrate is polysilicon, Ni, Ge, Pt, TiN, Al, tantalu-based nitride, silicide, a compound or mixture thereof, and so on. Furthermore, the substrate contains at least one dopant, which may be, for example, one from among IIIA or VA group, a compound or mixture thereof, and so on.

Next, as shown in FIG. 5B, a first insulating layer 520 and a conductor layer 530 are formed on the substrate 510, respectively. The material of the first insulating layer 520 does not react with the substrate 510 and/or the conductor layer 530. The material of the first insulating layer is an oxide such as SiO₂ or Al₂O₃, nitride such as SiNₓ, a high dielectric constant material, or the like. In addition, the material of the conductor layer is polysilicon, a metal material, or the like. The thickness of the first insulating layer is in the range of 10 nm to 50 nm, and the thickness of the conductor layer is in the range of 5 nm to 300 nm.

After that, as shown in FIG. 5C, a second insulating layer 540 is formed on the sidewalls of the first insulating layer 520 and the conductor layer 530. The second insulating layer 540 has multiple separated charge storage units 542 to store charges. Herein, the material of the second insulating layer is the same as or different from that of the first insulating layer. The material of the second insulating layer 540 does not react with the substrate 510, the conductor layer 530, and/or the charge storage units 542 therein. The material of the second insulating layer is an oxide such as SiO₂ or Al₂O₃, nitride such as SiNₓ, a high dielectric constant material, or the like. The dielectric constant of the first insulating layer is larger than that of the second insulating layer, so as to increase the coupling ratio of circuit operation and accelerate the operation speed. However, the dielectric constant of the second insulating layer is not less than that of SiO₂. The thickness of the second insulating layer is in the range of 5 nm to 20 nm.

Additionally, the material of the charge storage units is a semiconductor material, a metal material, or the like. Furthermore, the charge storage units can be nanometer dies.

The second insulating layer 540 separates the charge storage units from one another, and thus the phenomenon of crosstalk between the charge storage units is effectively eliminated. Furthermore, the charge storage units in the second insulating layer are arranged in a matrix of more than two dimensions. In other words, the charge storage units are arranged in at least two layers in the direction substantially perpendicular to the surface of the substrate, as shown in FIG. 5C, and arranged in at least one row in the direction substantially parallel to the surface of the substrate, as shown in FIGS. 5C and 5D. In other words, the multi-layer charge storage structure perpendicular to and parallel to the surface of the substrate is used to increase the charge storage capacity and provide multi-bit storage capability.

At last, as shown in FIGS. 5E and 5F, a source/drain region S/D is formed on both sides of a gate of the substrate 510, i.e., the conductor layer 530, and thus a non-volatile memory device is formed. The source/drain region S/D is formed through dopant doping or metal Schottky contact. The process of the dopant doping may be one from among ion-implantation, high temperature diffusion, and so on.

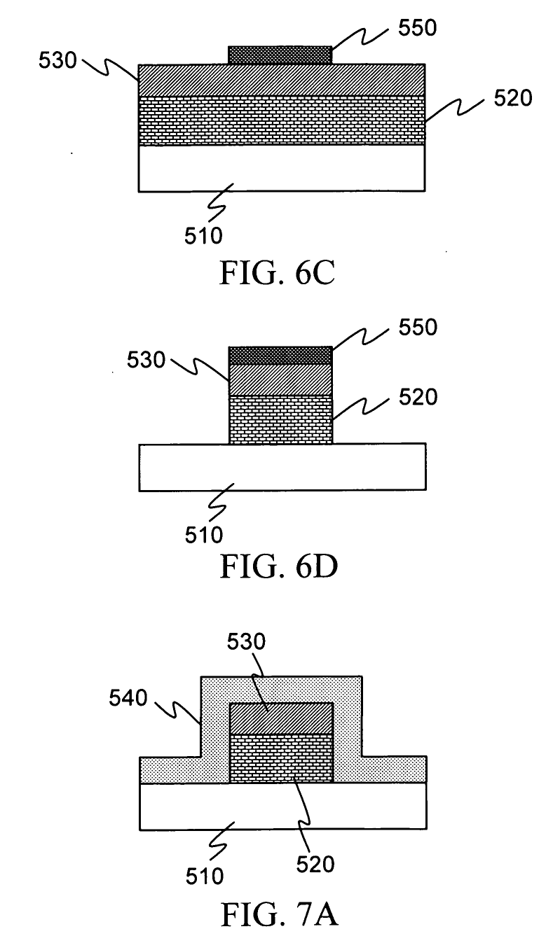

Additionally, the laminated first insulating layer and conductor layer are formed on the substrate through a mask process. Firstly, the first insulating layer 510 is grown on the substrate 510 as shown in FIG. 6A. Then, the conductor layer 530 is grown on the first insulating layer 520 as shown in FIG. 6B. After that, the gate range of an active operating region is defined to form a photoresist pattern 550 on the conductor layer 530 as shown in FIG. 6C. By using the photoresist pattern 550 as an etch mask, the first insulating layer 520 and the conductor layer 530 not covered by the photoresist pattern 550 are etched until the substrate 510 is exposed as shown in FIG. 6D. In other words, by using the photoresist pattern 550 as the etch mask, the insulating layer and the conductor layer except that in the gate region are removed through dry or wet etching. The photoresist pattern is then removed to form the structure as shown in FIG. 5B.

The conductor layer is grown on the first insulating layer through a process such as physical vapor deposition (PVD), plasma enhanced chemical vapor deposition (PE-CVD), chemical vapor deposition (CVD), atomic layer deposition (ALD), molecular beam epitaxy (MBE), anodization, electroless plating, and so on.

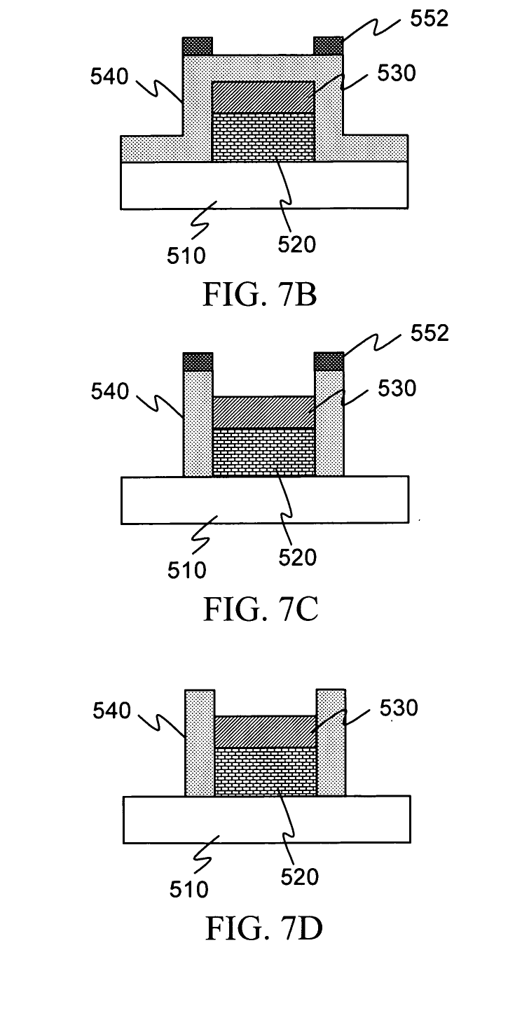

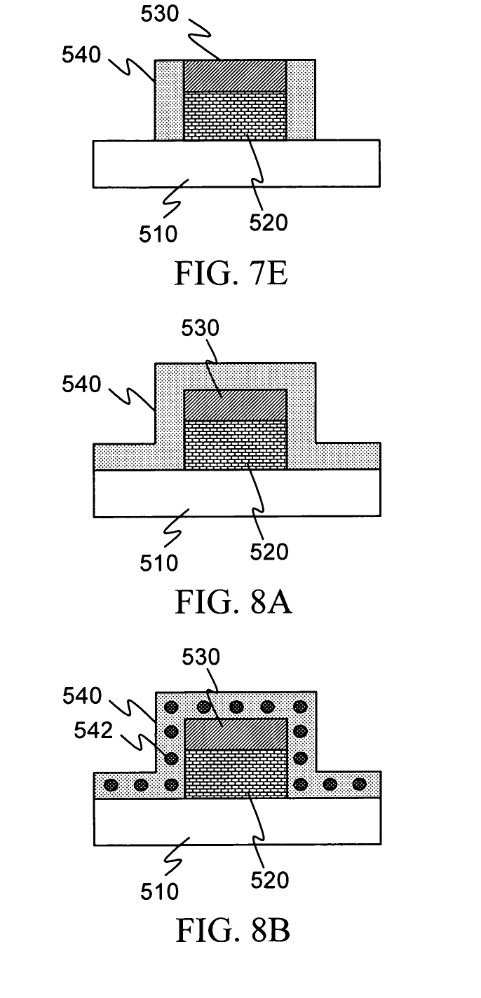

Furthermore, the second insulating layer is formed on the sidewalls of the first insulating layer and the conductor layer through a mask process and an annealing process. Firstly, as shown in FIG. 7A, the second insulating layer 540 is grown on the structure as shown in FIG. 5B. At this point, the second insulating layer 540 has contained the material of the charge storage units. Then, as shown in FIG. 7B, photoresist patterns 552 are formed on the second insulating layer 540 corresponding to the sidewalls of the first insulating layer 520 and the conductor layer 530. Further, as shown in FIG. 7C, by using the photoresist patterns 552 as the etch mask, the second insulating layer 540 not covered by the photoresist patterns 552 is etched to remove the second insulating layer 540 not covering the sidewalls of the first insulating layer 520 and the conductor layer 530. In other words, the second insulating layer 540 not covering the sidewalls of the gate, i.e., the conductor layer 530 is removed, through an anisotropic etching technique. Subsequently, as shown in FIG. 7D, the photoresist pattern 552 is removed. Then, as shown in FIG. 7E, the second insulating layer 540 is planarized by the chemical mechanical polishing (CMP) and/or etch back technique. The material of the charge storage units 542 is nucleated through an annealing process to form the charge storage units 542, and thus the structure as shown in FIG. 5C is obtained.

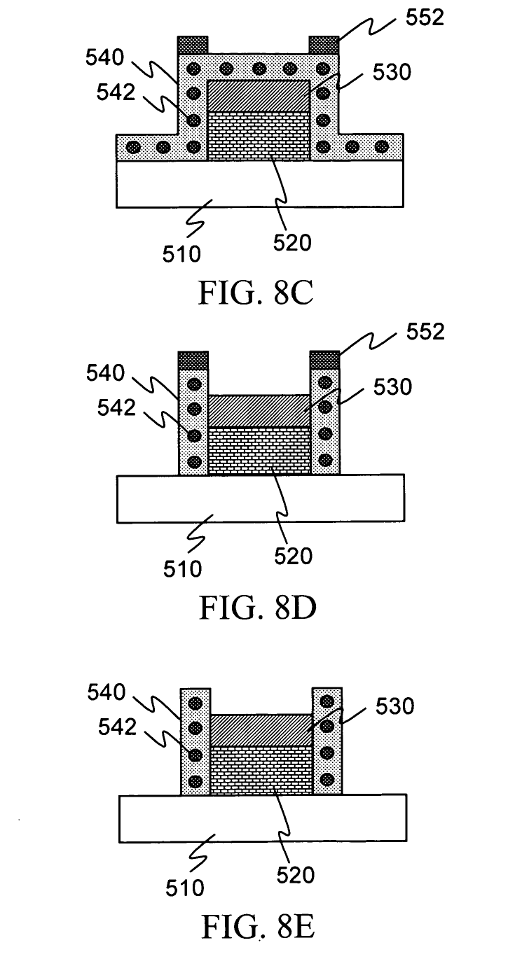

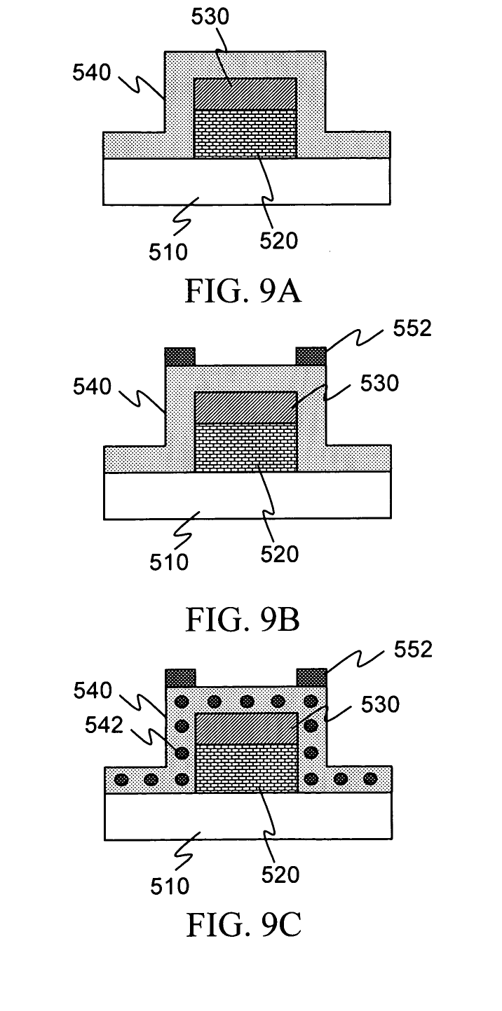

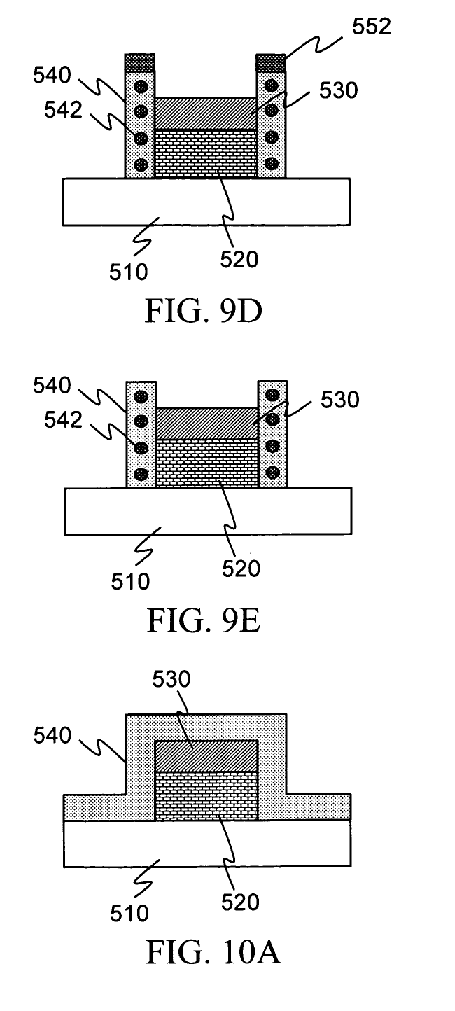

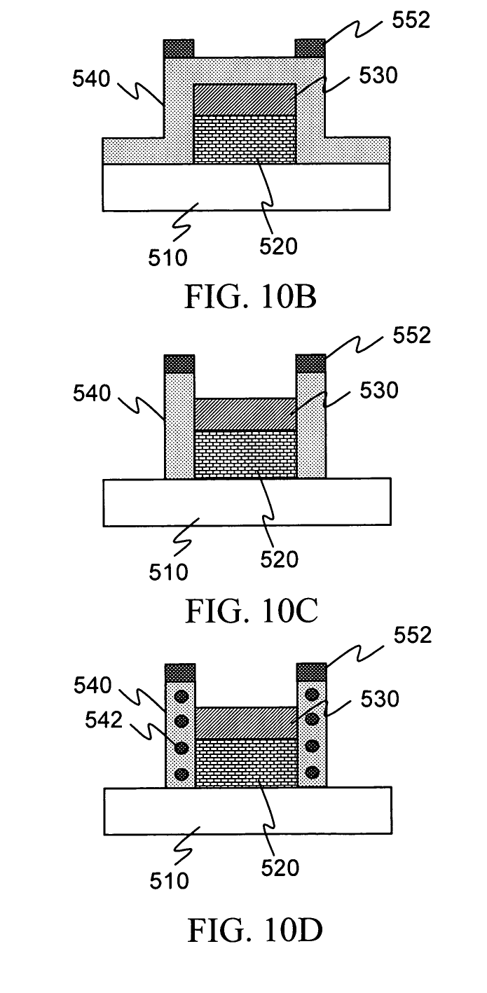

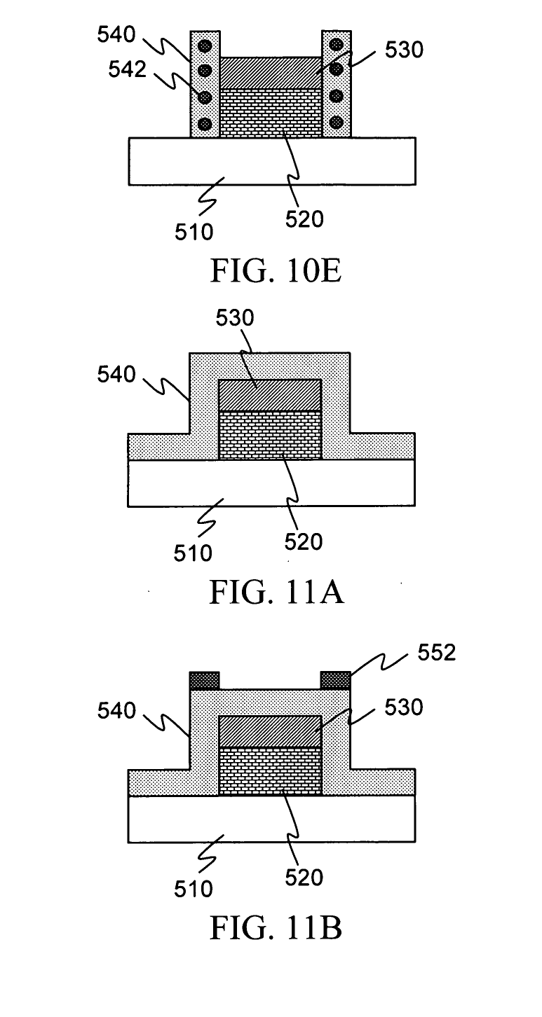

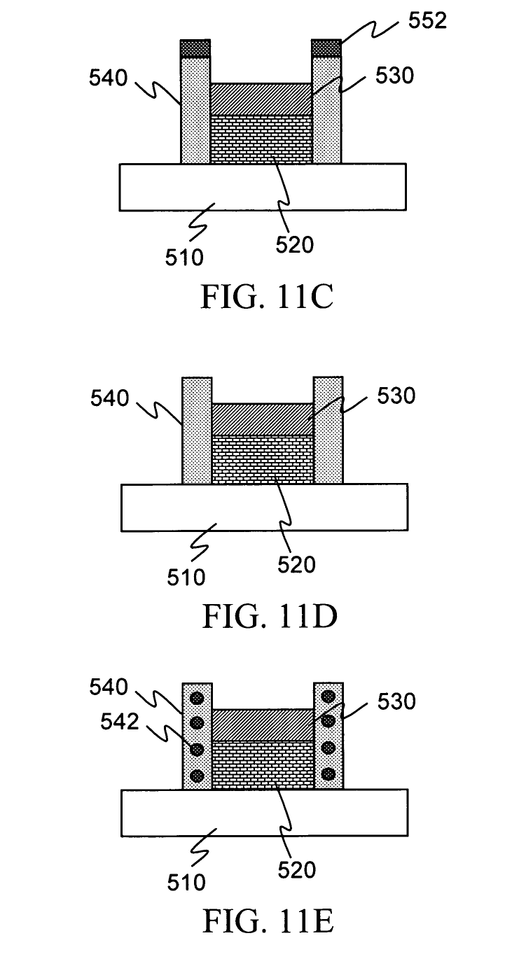

Additionally, the annealing process is also implemented during other stages of the manufacturing process of the device. For example, the annealing process is performed after the second insulating layer 540 is grown (referring to FIGS. 8A to 8E), before (referring to FIGS. 9A to 9E) or after (referring to FIGS. 10A to 10E) the insulating layer 540 is etched, or before the second insulating layer 540 is planarized (referring to FIGS. 11A to 11E), and thus the structure as shown in FIG. 5C is obtained after the second insulating layer is planarized. Furthermore, the annealing process can be performed in follow-up processing of the device.

Furthermore, the second insulating layer grown on the structure as shown in FIG. 5B does not contain the material of the charge storage units. After the second insulating layer is etched, the material of the charge storage units is implanted into the second insulating layer by dopant doping. The material of the charge storage units is nucleated through an annealing process to form the charge storage units, wherein the process of the dopant doping may be one from among ion-implantation, diffusion, and so on.

Besides, the non-volatile memory device of the present invention as shown in FIGS. 5D and 5E can be achieved through other types of semiconductor processes.

In view of the above, since the second insulating layer is separated by the first insulating layer, the problems existing in the conventional fabricating method, i.e., the charge storage units are located in the continuous insulating thin films parallel to the plane of the substrate, are eliminated. The problems include that data cannot be well reserved and the purpose of the binary storage cannot be effectively achieved because the charges stored in the charge storage units are laterally migrated to another side. Furthermore, according to the present invention, the first insulating layer contains the high dielectric coefficient material to increase the coupling ratio when the device operates, thereby accelerating the reading/writing speed. Furthermore, according to the present invention, the second insulating layer contains at least two layers of separated charge storage units perpendicular to the plane of the substrate. As such, the threshold voltage of the device is increased after the charges are programmed, thus enhancing the capability to interpret data.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A non-volatile memory device, comprising: a substrate;
a first insulating layer formed on the substrate;
a conductor layer formed on the first insulating layer;
a second insulating layer formed on the substrate and covering the sidewalls of the first insulating layer and the conductor layer; and
a plurality of charge storage units formed in the second insulating layer.

2. The non-volatile memory device as claimed in claim 1, wherein the charge storage units are arranged in at least two layers in a direction perpendicular to the surface of the substrate or at least one row in a direction substantially parallel to the surface of the substrate.

3. The non-volatile memory device as claimed in claim 1, wherein the dielectric constant of the first insulating layer is greater than that of the second insulating layer.

4. The non-volatile memory device as claimed in claim 1, wherein the dielectric constant of the second insulating layer is greater than that of silicon dioxide.

5. The non-volatile memory device as claimed in claim 1, wherein the material of the charge storage units is a semiconductor material or a metal material.

6. The non-volatile memory device as claimed in claim 1, wherein the size of the charge storage unit is of a nanometer level.

7. The non-volatile memory device as claimed in claim 1, wherein the substrate is a semiconductor substrate.

8. The non-volatile memory device as claimed in claim 7, wherein the semiconductor substrate contains at least one dopant.

9. The non-volatile memory device as claimed in claim 1, wherein the material of the first insulating layer comprises at least one of an oxide, nitride, and a high dielectric constant material.

10. The non-volatile memory device as claimed in claim 1, wherein the material of the second insulating layer comprises at least one of an oxide, nitride, and a high dielectric constant material.

11. The non-volatile memory device as claimed in claim 1, wherein the material of the conductor layer is a polysilicon or a metal material.

12. The non-volatile memory device as claimed in claim 1, further comprising: at least one source/drain region formed on both sides of a gate area of the substrate.

13. The non-volatile memory device as claimed in claim 12, wherein the process for forming source/drain region is a dopant doping or metal Schottky contact.

14. The non-volatile memory device as claimed in claim 13, wherein the dopant doping is ion implantation or diffusion.

15. A method of fabricating the non-volatile memory device, comprising:
providing a substrate;
forming a first insulating layer and a conductor layer on the substrate, respectively; and
forming a second insulating layer on the sidewalls of the first insulating layer and the conductor layer, wherein a plurality of separated charge storage units is formed in the second insulating layer.

16. The method of fabricating the non-volatile memory device as claimed in claim 15, wherein the charge storage units are arranged in at least two layers in a direction perpendicular to the surface of the substrate or at least one row in a direction parallel to the surface of the substrate.

17. The method of fabricating the non-volatile memory device as claimed in claim 15, wherein the dielectric constant of the first insulating layer is greater than that of the second insulating layer.

18. The method of fabricating the non-volatile memory device as claimed in claim 15, wherein the dielectric constant of the second insulating layer is greater than that of silicon dioxide.

19. The method of fabricating the non-volatile memory device as claimed in claim 15, wherein the step of forming a second insulating layer on the sidewalls of the first insulating layer and the conductor layer comprises:
growing the second insulating layer to cover the substrate, the first insulating layer, and the conductor layer;
forming a photoresist pattern on the second insulating layer corresponding to the sidewalls of the first insulating layer and the conductor layer;
etching the second insulating layer not being covered by the photoresist pattern with the photoresist patter as an etch mask, so as to remove the second insulating layer not covering the sidewalls of the first insulating layer and the conductor layer;
removing the photoresist pattern;
planarizing the second insulating layer;
implanting the material of the charge storage units into the second insulating layer by means of dopant doping; and
performing an annealing process to nucleate the material of the charge storage units, thereby forming the charge storage units.

20. The method of fabricating the non-volatile memory device as claimed in claim 19, wherein the dopant doping is an ion-implantation or diffusion.

21. The method of fabricating the non-volatile memory device as claimed in claim 15, wherein the step of forming a second insulating layer on the sidewalls of the first insulating layer and the conductor layer comprises:
growing the second insulating layer to cover the substrate, the first insulating layer, and the conductor layer;
forming a photoresist pattern on the second insulating layer corresponding to the sidewalls of the first insulating layer and the conductor layer;
etching the second insulating layer not being covered by the photoresist pattern with the photoresist patter as an etch mask, so as to remove the second insulating layer not covering the sidewalls of the first insulating layer and the conductor layer;
removing the photoresist pattern; and
planarizing the second insulating layer.

22. The method of fabricating the non-volatile memory device as claimed in claim 21, when the second insulating layer does not contain the material of the charge storage units, further comprising:
implanting the material of the charge storage units into the second insulating layer by means of dopant doping; and
performing an annealing process to nucleate the material of the charge storage units, thereby forming the charge storage units.

23. The method of fabricating the non-volatile memory device as claimed in claim 22, wherein the dopant doping is an ion-implantation or diffusion.

24. The method of fabricating the non-volatile memory device as claimed in claim 21, when the second insulating layer contains the material of the charge storage units, further comprising:
performing an annealing process to nucleate the material of the charge storage units, thereby forming the charge storage units.

25. The method of fabricating the non-volatile memory device as claimed in claim 21, wherein the step of planarizing the second insulating layer is performed through at least one of chemical mechanical polishing and an etch back technique.

26. The method of fabricating the non-volatile memory device as claimed in claim 15, wherein the step of laminating a first insulating layer and a conductor layer on the substrate comprises:
growing the first insulating layer on the substrate;
growing the conductor layer on the first insulating layer;
forming a photoresist pattern on the conductor layer;
etching the first insulating layer and the conductor layer not being covered by the photoresist pattern with the photoresist pattern as an etch mask, until the substrate and the conductor layer are exposed; and
removing the photoresist pattern.

27. The method of fabricating the non-volatile memory device as claimed in claim 15, wherein the material of the charge storage units is a semiconductor material or a metal material.

28. The method of fabricating the non-volatile memory device as claimed in claim 15, wherein the size of the charge storage unit is of a nanometer level.

29. The method of fabricating the non-volatile memory device as claimed in claim 15, wherein the substrate is a semiconductor substrate.

30. The method of fabricating the non-volatile memory device as claimed in claim 29, wherein the semiconductor substrate comprises at least one dopant.

31. The method of fabricating the non-volatile memory device as claimed in claim 15, wherein the material of the first insulating layer comprises at least one of an oxide, nitride, and a high dielectric constant material.

32. The method of fabricating the non-volatile memory device as claimed in claim 15, wherein the material of the second insulating layer comprises at least one of an oxide, nitride, and a high dielectric constant material.

33. The method of fabricating the non-volatile memory device as claimed in claim 15, wherein the material of the conductor layer is a polysilicon or a metal material.

34. The method of fabricating the non-volatile memory device as claimed in claim 15, after the step of forming a second insulating layer on the sidewalls of the first insulating layer and the conductor layer, further comprising forming at least one source/drain region on both sides of a gate area of the substrate.

35. The method of fabricating the non-volatile memory device as claimed in claim 34, wherein the process for forming the source/drain region is a dopant doping or metal Schottky contact.

36. The method of fabricating the non-volatile memory device as claimed in claim 35, wherein the dopant doping is an ion implantation or diffusion.
